(19) United States
(12) Patent Application Publication
(10) Pub. No.: US 2025/0301895 A1
(43) Pub. Date: Sep. 25, 2025

(54) DISPLAY DEVICE AND ELECTRONIC DEVICE INCLUDING THE DISPLAY DEVICE

(71) Applicant: Samsung Display Co., Ltd., Yongin-si (KR)

(72) Inventors: OHJUNE KWON, Yongin-si (KR); HYOJEONG KWON, Yongin-si (KR); JEONGSEOK LEE, Yongin-si (KR)

(21) Appl. No.: 19/031,536

(22) Filed: Jan. 18, 2025

(30) Foreign Application Priority Data
Mar. 20, 2024 (KR) 10-2024-0038403

(51) Int. Cl. H10K 59/80; H10K 59/12; H10K 102/00

(52) U.S. Cl. CPC H10K 59/8792; H10K 59/1201; H10K 2102/311

(57) ABSTRACT

A display device includes a base layer, a display element layer on the base layer, and a light absorbing layer under the base layer and having a maximum light transmittance in a wavelength range of about 240 nm to about 550 nm. Thus, reflection of external light may be reduced, and excellent or suitable reliability may be exhibited because the light absorbing layer is sufficiently suitably cured in a wavelength range in which a light transmittance becomes maximum or is maximized.

### CROSS-REFERENCE TO RELATED APPLICATION

The present application claims priority to and the benefit of Korean Patent Application No. 10-2024-0038403, filed on Mar. 20, 2024, in the Korean Intellectual Property Office, the entire disclosure of which is incorporated herein by reference.

### BACKGROUND

### 1. Field

Embodiments of the present disclosure described herein are related to a display device, and for example, to a display device having improved external light reflection. Embodiments of the present disclosure are related to an electronic device including the display device.

### 2. Description of Related Art

Various display devices used for multimedia devices such as a television, a mobile phone, a tablet computer, and/or a game console are being developed. A display device may be a rigid type (or kind) or a flexible type (or kind) which is deformable, for example, foldable, rollable, bendable, and/or the like.

Members for reducing reflection of external light are used to improve display quality in various types (or kinds) of display devices. However, for the development of members for improving reflection, it is necessary or desirable for the members not only to exhibit excellent or suitable optical properties by suitably or sufficiently absorbing external light, but also to have excellent or suitable durability and reliability according to a usage state of the display device.

The information disclosed in this Background section is intended to enhance understanding of the background of the disclosure and therefore it may contain information that does not constitute prior art.

### SUMMARY

Aspects according to one or more embodiments of the present disclosure are directed toward a display device in which light in the entire visible light wavelength range is absorbed favorably and thus light introduced into an interior of the display device, reflected, and then extracted to the outside is minimized or reduced.

Additionally, aspects according to one or more embodiments of the present disclosure are directed toward a display device including a light absorbing layer which has excellent or suitable light absorption, may be more easily applied in manufacture of the display device, and has excellent or suitable reliability.

Additional aspects of embodiments will be set forth in part in the description which follows and, in part, will be apparent from the description, or may be learned by practice of the presented embodiments of the disclosure.

In one or more embodiments of the present disclosure, a display device includes: a base layer; a display element layer on the base layer; and a light absorbing layer under the base layer and having a maximum light transmittance in a wavelength range of about 240 nm to about 550 nm.

In one or more embodiments, the base layer may include a polyimide film having flexibility.

In one or more embodiments, the base layer may have a maximum light transmittance in a wavelength range of about 500 nm to about 850 nm.

In one or more embodiments, the light absorbing layer may include: a first sub-light absorbing layer having a maximum light transmittance in a first wavelength range; and a second sub-light absorbing layer between the first sub-light absorbing layer and the base layer and having a maximum light transmittance in a second wavelength range having a longer wavelength than the first wavelength range.

In one or more embodiments, the base layer may include a transparent glass substrate having a light transmittance of about 80% or more in a wavelength range of about 300 nm to about 800 nm.

In one or more embodiments, the light absorbing layer may include: a first sub-light absorbing layer having a maximum light transmittance in a wavelength range of about 300 nm to about 450 nm; a second sub-light absorbing layer between the first sub-light absorbing layer and the base layer and having a maximum light transmittance in a wavelength range of about 500 nm to about 600 nm; and a third sub-light absorbing layer between the second sub-light absorbing layer and the base layer and having a maximum light transmittance in a wavelength range of about 650 nm to about 800 nm.

In one or more embodiments, the light absorbing layer may include a base resin, and at least one colorant of a blue colorant or a green colorant.

In one or more embodiments, the light absorbing layer may be directly below the base layer.

In one or more embodiments of the present disclosure, a display device includes: a base layer having a maximum light transmittance in a first wavelength range; a display element layer on the base layer and including a light-emitting element; and a light absorbing layer under the base layer and having a maximum light transmittance in a second wavelength range having a shorter wavelength than the first wavelength range.

In one or more embodiments, the base layer may be a polyimide film having a maximum light transmittance in a wavelength range of about 500 nm to about 850 nm.

In one or more embodiments, the light absorbing layer may include a first sub-light absorbing layer having a maximum light transmittance in a wavelength range of about 300 nm to about 450 nm.

In one or more embodiments, the light absorbing layer may further include a second sub-light absorbing layer between the first sub-light absorbing layer and the base layer and having a maximum light transmittance in a wavelength range of about 500 nm to about 600 nm.

In one or more embodiments, the second sub-light absorbing layer may be directly below the base layer, and the first sub-light absorbing layer may be directly below the second sub-light absorbing layer.

In one or more embodiments, the light absorbing layer may be directly below the base layer.

In one or more embodiments, the display device may further include an optical layer on the display element layer and including a polarization layer.

In one or more embodiments of the present disclosure, a display device includes: a display element layer including a light-emitting element; a base layer below the display element layer and having an absorbance of first light of about 80% or more; and a light absorbing layer directly below the base layer and having an absorbance of second light of about 80% or more, the second light having a longer wavelength than the first light.

In one or more embodiments, the first light may have a wavelength in a range of about 240 nm to about 550 nm, and the second light may have a wavelength in a range of about 500 nm to about 850 nm.

In one or more embodiments, the light absorbing layer may be configured to transmit ultraviolet light.

In one or more embodiments, the light absorbing layer may include a plurality of sub-light absorbing layers, and the sub-light absorbing layers may include a first sub-light absorbing layer which is below the base layer and is configured to transmit ultraviolet light, and a second sub-light absorbing layer which is between the first sub-light absorbing layer and the base layer, and is configured to absorb the ultraviolet light and is configured to transmit infrared light.

In one or more embodiments, the base layer may be a polyimide film, and the light absorbing layer may include at least one of a blue colorant or a green colorant.

An electronic device according to one or more embodiments of the present disclosure includes the preceding display device as described herein. In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to one or more embodiments;

FIG. 2 is an exploded perspective view of a display device according to one or more embodiments;

FIG. 3 is a cross-sectional view of a display device of one or more embodiments, illustrating a part taken along line I-I′ of FIG. 2;

FIG. 4 is an enlarged cross-sectional view of a partial region of a display device;

FIG. 5 illustrates light transmittance properties in a display device of one or more embodiments;

FIG. 6 schematically illustrates light absorbing characteristics in a display device of one or more embodiments;

FIG. 7 is a cross-sectional view of a display device of one or more embodiments;

FIG. 8 is a cross-sectional view of a display device of one or more embodiments;

FIG. 9 illustrates light transmittance properties in a display device of one or more embodiments;

FIGS. 10A-10C are views illustrating some steps of manufacturing a display device according to one or more embodiments; and

FIGS. 11A-11D are views illustrating some steps of manufacturing a display device according to one or more embodiments.

### DETAILED DESCRIPTION

The subject matter of the present disclosure may be implemented to have various suitable modifications and have various suitable forms, and example embodiments are illustrated in the drawings and described in more detail in the text. It is to be understood, however, that the present disclosure is not intended to be limited to the particular forms disclosed, but on the contrary, is intended to cover all modifications, equivalents, and alternatives falling within the spirit and scope of the present disclosure.

In this specification, it will be understood that when an element (or region, layer, portion, or the like) is referred to as being “on”, “connected to” or “coupled to” another element, it may be directly arranged/connected/coupled to another element, or intervening elements may be arranged therebetween.

Like reference numerals or symbols refer to like elements throughout. Also, in the drawings, the thicknesses, the ratios, and the dimensions of the elements may be exaggerated for effective description of the technical contents. The term “and/or” includes all combinations of one or more of the associated listed elements.

Although the terms first, second, etc., may be used to describe one or more suitable elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms are a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

In this specification, it will be understood that “being directly arranged”

means that there are no intervening layers, films, regions, plates, or the like between a portion of layers, films, regions, plates, or the like and another portion. For example, “being directly arranged” may mean to be arranged between two layers or two members without using an additional member such as an adhesive member and/or the like.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device of one or more embodiments will be described in more detail with reference to the drawings.

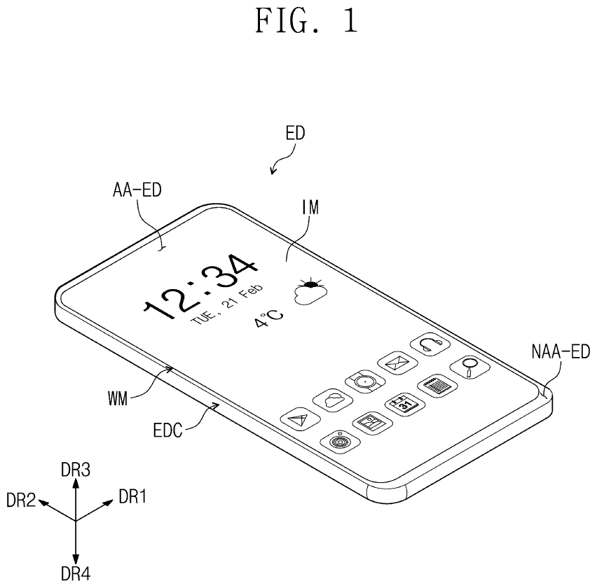

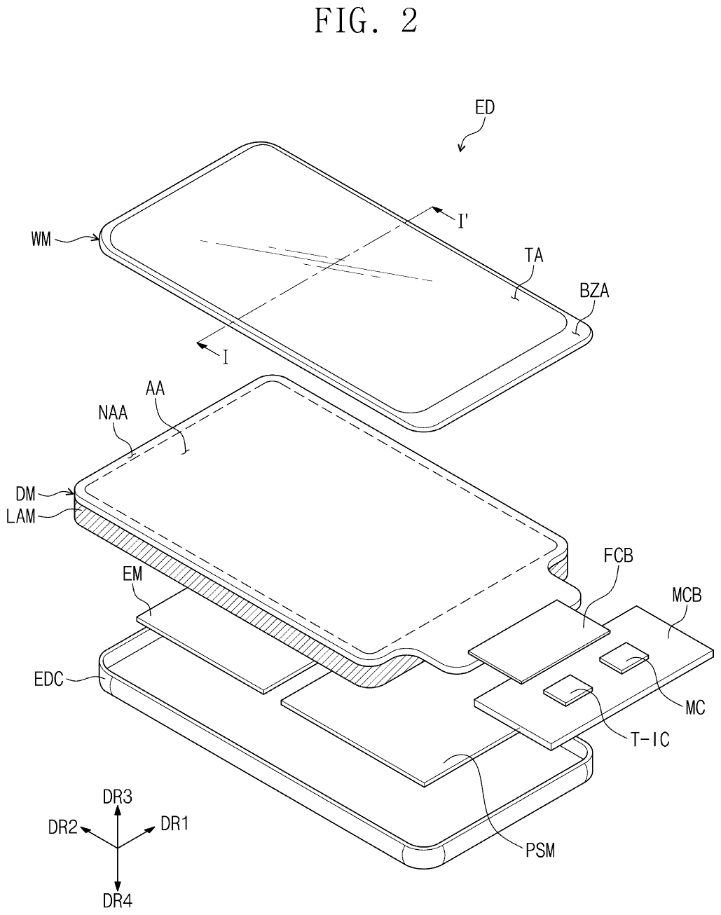

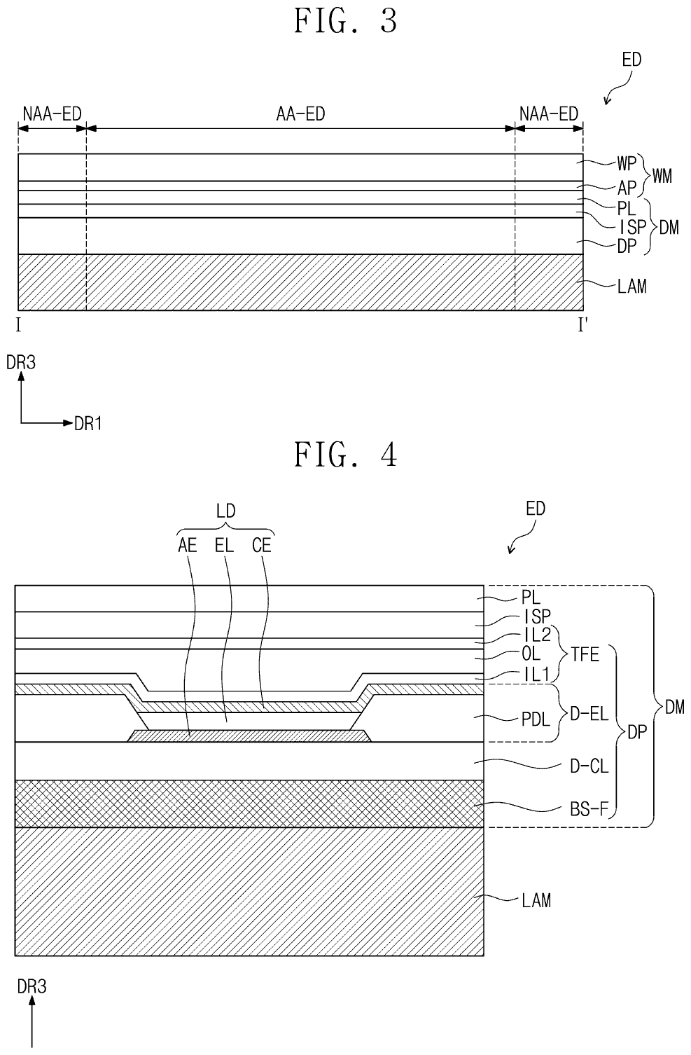

FIG. 1 is a perspective view illustrating a display device according to one or more embodiments. FIG. 2 is an exploded perspective view of a display device according one or more embodiments. FIG. 3 is a cross-sectional view of a display device according to one or more embodiments. FIG. 3 may be a cross-sectional view taken along line I-I′ of FIG. 2.

Referring to FIG. 1, a display device ED may be activated in response to an electrical signal and display images. For example, the display device ED may be a large-sized device such as a television or an outdoor billboard, as well as a medium- and small-sized device such as a monitor, a mobile phone, a tablet computer, a car navigation unit, and/or a game console. However, one or more embodiments of the display device ED are presented as examples, and the display device ED is not limited to any one embodiment without departing from the spirit or scope of the present disclosure.

The display device ED may be rigid or flexible. The wording “flexible” means having a bendable property (e.g., being bendable). For example, the flexible display device ED may include a curved device, a rollable device, and/or a foldable device.

In one or more embodiments, in FIG. 1 and the following drawings, a first direction axis DR1 to a fourth direction axis DR4 are illustrated, and directions indicated by the first to fourth direction axes DR1, DR2, DR3, and DR4 described herein may have a relative concept and may thus be changed to other directions. In embodiments, the directions indicated by the first to fourth direction axes DR1, DR2, DR3, and DR4 may be referred to as first to fourth directions DR1, DR2, DR3, and DR4, and may be denoted as the same reference numerals or symbols. In this specification, the first direction axis DR1 and the second direction axis DR2 may be orthogonal to each other, and the third direction axis DR3 and the fourth direction axis DR4 may each be a normal direction of a plane defined by the first direction axis DR1 and the second direction axis DR2. In one or more embodiments, the third direction axis DR3 and the fourth direction axis DR4 may be opposite to each other.

A thickness direction of the display device ED may be parallel to the third direction axis DR3 which is the normal direction of the plane defined by the first direction axis DR1 and the second direction axis DR2. The display device ED may provide an image IM to a user through a display surface. In this specification, a front surface (or upper surface) and a rear surface (or lower surface) of each of components are defined based on a direction in which the image IM is displayed. In this specification, the direction of the third direction axis DR3 may be defined as a direction in which the image IM is displayed, and the direction of the fourth direction axis DR4 may be defined as a direction opposite to the third direction axis DR3.

In this specification, the wording “on a plane” may be defined as a state when viewed in the third direction DR3. In this specification, the wording “on a cross section” may be defined as a state when viewed in the first direction DR1 or the second direction DR2. In one or more embodiments, the directions indicated by the first to fourth directions DR1, DR2, DR3 and DR4 have a relative concept, and may thus be changed to other directions.

The display device ED according to one or more embodiments may display the image IM through an active region AA-ED. The active region AA-ED may include a flat surface defined by the first direction DR1 and the second direction DR2. The active region AA-ED may further include a curved surface bent from at least one side of the flat surface defined by the first direction DR1 and the second direction DR2. A surface, on which the image IM is displayed, may correspond to a front surface of the display device ED. The image IM may include not only a dynamic image but also a static image.

A peripheral region NAA-ED may be adjacent to the active region AA-ED. The peripheral region NAA-ED may be around (e.g., surround) the active region AA-ED. Accordingly, a shape of the active region AA-ED may be substantially defined by the peripheral region NAA-ED. However, this is illustrated as an example, and the present disclosure is not limited thereto. The peripheral region NAA-ED may be adjacent to only one side of the active region AA-ED or may not be provided. The display device ED according to one or more embodiments of the present disclosure may include an active region having one or more suitable shapes, but is not limited to any one embodiment.

On a plane, the display device ED may have a rectangular shape which has short sides extending in the first direction DR1 and long sides extending in the second direction DR2 crossing the first direction DR1. However, one or more embodiments of the present disclosure is not limited thereto, and on a plane, the display device ED may have one or more suitable shapes, such as a circular or a polygonal shape.

In one or more embodiments, the display device ED of one or more embodiments may be a flexible display device. At least a partial region of the display device ED of one or more embodiments may be bent and deformed. In one or more embodiments, the display device ED may be a foldable device which is variably or suitably deformed into a folded state or a non-folded state with respect to at least one folding axis being extended in one direction.

The display device ED of one or more embodiments may detect an external input applied from the outside. The external input may include one or more suitable types (or kinds) of inputs such as force, pressure, temperature, and light.

Referring to FIGS. 1-3, the display device ED of one or more embodiments includes a display module DM. The display module DM may be a component which is configured to generate an image and configured to detect an input applied from the outside. The display module DM according to one or more embodiments may include a display panel DP and an input sensor ISP on the display panel DP. In one or more embodiments, the display module DM may further include an optical layer PL on the input sensor ISP.

The display device ED of one or more embodiments may include a window module WM above the display module DM. In one or more embodiments, the display device ED may further include an electronic module EM, a power supply module PSM, a housing EDC, and/or the like.

An active region AA and a peripheral region NAA may be defined in the display module DM according to one or more embodiments. The active region AA may be activated in response to an electrical signal. The peripheral region NAA may be located adjacent to at least one side of the active region AA.

The active region AA may correspond to the active region AA-ED of the display device illustrated in FIG. 1. The peripheral region NAA may be around (e.g., may surround) the active region AA. However, one or more embodiments of the present disclosure is not limited thereto, and unlike what is illustrated in FIG. 2, and/or the like, a portion of the peripheral region NAA may not be provided. The peripheral region NAA may correspond to the peripheral region NAA-ED of the display device illustrated in FIG. 1.

The display module DM according to one or more embodiments may include the peripheral region NAA on at least one side of the active region AA, and a driving circuit, a driving line, and/or the like for driving the active region AA may be in the peripheral region NAA.

The window module WM may be on the display module DM and may be configured to protect the display module DM against external impacts and/or scratches. The window module WM may cover the exterior (e.g., the entire exterior) of the display module DM. A front surface of the window module WM may correspond to an upper surface of the display device ED described above.

In one or more embodiments, the window module WM may include a base substrate WP which is an optically transparent insulating material. The base substrate WP may include an optically transparent insulating material. The base substrate WP may include at least one of a glass substrate or a synthetic resin film. The base substrate WP may have a single-layered structure, or a multi-layered structure in which a plurality of films are coupled. The window module WM may further include a functional layer such as an anti-fingerprint layer, a phase control layer, and/or a hard coating layer, which are on the base substrate WP.

The window module WM may further include an adhesive layer AP. The base substrate WP and the display module DM may be bonded via the adhesive layer AP. However, one or more embodiments of the present disclosure is not limited thereto. The adhesive layer AP may not be provided, and the window module WM may be directly on the display module DM.

The window module WM may be divided into a transmission part TA and a bezel part BZA. The transmission part TA may correspond to the active region AA of the display module DM, and the bezel part BZA may correspond to the peripheral region NAA of the display module DM. The bezel part BZA may define a shape of the transmission part TA. The bezel part BZA may be adjacent to the transmission part TA and be around (e.g., surround) the transmission part TA. However, one or more embodiments of the present disclosure is not limited to what is illustrated in the drawings, and the bezel part BZA may be adjacent to only one side of the transmission part TA, or a portion thereof may not be provided.

The display module DM may further include a main circuit board MCB, a flexible circuit film FCB, a sensor control circuit T-IC, and a main controller MC.

The main circuit board MCB may be electrically connected to the display module DM via the flexible circuit film FCB. The main circuit board MCB may be electrically connected to an electronic module EM via a connector.

The flexible circuit film FCB may be connected to each of the display panel DP and the input sensor ISP to electrically connect the display panel DP and the input sensor ISP to the main circuit board MCB. In one or more embodiments, the input sensor ISP may be electrically connected to the display panel DP and also be electrically connected to the main circuit board MCB via the flexible circuit film FCB. However, one or more embodiments of the present disclosure is not limited thereto, and the input sensor ISP may be electrically connected to the main circuit board MCB via an additional flexible circuit film. In one or more embodiments, the flexible circuit film FCB may not be provided, and the main circuit board MCB may be directly connected to the display panel DP.

The sensor control circuit T-IC and the main controller MC may each be provided in a form of an integrated chip. The sensor control circuit T-IC and the main controller MC may be mounted on the main circuit board MCB. However, one or more embodiments of the present disclosure is not limited thereto.

The main controller MC may control an overall operation of the display device ED. For example, the main controller MC may control operations of the display panel DP and the input sensor ISP. In one or more embodiments, the main controller MC may control an operation of the electronic module EM. The main controller MC may include at least one microprocessor.

In one or more embodiments, the display module DM may include a data driver including a driving circuit for driving pixels of the display panel DP. The data driver may receive image data and control signals from the main controller MC. For example, the control signals may include an input vertical synchronization signal, an input horizontal synchronization signal, a main clock, a data enable signal, and/or the like. The data driver may be mounted on the peripheral region NAA of the display panel DP.

The sensor control circuit T-IC may provide, to the input sensor ISP, electrical signals for driving the input sensor ISP. The sensor control circuit T-IC may receive a control signal, such as a clock signal, from the main controller MC.

The electronic module EM may include one or more suitable functional modules required or desired for driving the display device ED. For example, the electronic module EM may include a wireless communication module, an image input module, a sound input module, a sound output module, a memory, an external interface module, and/or the like. The above-described modules of the electronic module EM may be mounted on the main circuit board MCB, or may be electrically connected to the main circuit board MCB via an additional flexible circuit board.

The power supply module PSM may be electrically connected to the electronic module EM. The power supply module PSM may supply power required or desired for an overall operation of the display device ED. For example, the power supply module PSM may include a battery device.

The window module WM and the housing EDC may be coupled to each other to constitute the exterior of the display device ED. The window module WM and the housing EDC may be coupled to form an inner space in which components of the display device ED are accommodated. For example, the components of the display device ED may be accommodated in an inner space formed by the window module WM and the housing EDC. The display module DM, the flexible circuit film FCB, the main circuit board MCB, the electronic module EM, the power supply module PSM, and/or the like, may be accommodated in the above-described inner space. A portion of the display module DM may be bent such that the flexible circuit film FCB and the main circuit board MCB face a rear surface of the display module DM, and may be accommodated in the housing EDC.

The housing EDC may include a material having relatively high rigidity. For example, the housing EDC may include glass, plastic, and/or metal and/or include frames and/or plates composed of combinations thereof. The housing EDC may absorb an impact applied from the outside, or prevent or reduce infiltration of impurities/moisture, and/or the like, from the outside, thereby protecting the display module DM, and/or the like, accommodated in the housing EDC.

In the display device ED of one or more embodiments, the display panel DP may be configured to generate (e.g., substantially generate) images. The display panel DP may be a light-emitting display panel. For example, the display panel DP may be an organic light-emitting display panel, an inorganic light-emitting display panel, a quantum dot display panel, a micro LED display panel, and/or a nano LED display panel. The display panel DP may be referred to as a display layer.

Referring to FIGS. 2-3, the display module DM may further include an optical layer PL above the display panel DP. The optical layer PL may be on the input sensor ISP. The optical layer PL may be a reflection reduction layer which is configured to reduce reflectance for external light incident from the outside of the display module DM. The optical layer PL may be formed on the input sensor ISP through a continuous process. In one or more embodiments, the optical layer PL may include a polarization layer.

For example, the optical layer PL may include a polarization layer including a retarder and/or a polarizer, multi-layered reflective layers which cause destructive interference of reflected light, and/or color filters which correspond to a pixel arrangement and an emission color of the display panel DP. For example, when the optical layer PL includes color filters, the color filters may be arranged in consideration of emission colors of pixels included in the display panel DP. Also, in one or more embodiments, the optical layer PL may not be provided.

The display device ED of one or more embodiments may include a light absorbing layer LAM under the display module DM. The light absorbing layer LAM may be directly below the display module DM. The light absorbing layer LAM may absorb at least a portion of light among light incident from the outside of the display device ED to the display module DM. At least a portion of the light provided from the outside of the display device ED is absorbed by the light absorbing layer LAM, and thus light reflected from the display device ED and emitted to the outside may be minimized or reduced.

FIG. 4 is an enlarged cross-sectional view of a part of a display device. In FIG. 4, some components of a display device ED are not provided, and the configuration of a display module DM and a light absorbing layer LAM is illustrated in more detail. FIG. 4 illustrates only one light-emitting element and the peripheral portion thereof in the active region AA (see FIG. 2), and FIG. 4 and the contents described with reference thereto may be similarly applied to other light-emitting elements and the peripheral portions thereof in the active region AA (see FIG. 2).

In one or more embodiments, the display module DM includes a display panel DP, an input sensor ISP, and an optical layer PL, and the display panel DP includes a base layer BS-F, a circuit layer D-CL, a display element layer D-EL, and an encapsulation layer TFE. In one or more embodiments, the light absorbing layer LAM may be under the base layer BS-F. The light absorbing layer LAM may be directly below the base layer BS-F.

The base layer BS-F may be a member which is configured to provide a base surface on which the circuit layer D-CL is thereon. The base layer BS-F may be a rigid substrate, or a flexible substrate which is bendable, foldable, rollable, and/or the like. The base layer BS-F may be a glass substrate, a metal substrate, a polymer substrate, and/or the like. However, one or more embodiments of the present disclosure is not limited thereto, and the base layer BS-F may be an inorganic layer, an organic layer, or a composite material layer including an inorganic layer and an organic layer.

In some aspects illustrated in FIG. 4, and/or the like, the base layer BS-F may include a flexible polymer film. For example, in one or more embodiments, the base layer BS-F may be a flexible polyimide film.

When the base layer BS-F of one or more embodiments is a polyimide film, the base layer BS-F may have a maximum light transmittance in a first wavelength range. The base layer BS-F may have a maximum light transmittance in a wavelength range of about 500 nm to about 850 nm. For example, the base layer BS-F may have a maximum light transmittance in a wavelength range of about 550 nm to about 800 nm. In one or more embodiments, the base layer BS-F may exhibit a light transmittance of about 30% or more in a wavelength range of about 550 nm to about 800 nm. In one or more embodiments, the base layer BS-F according to one or more embodiments may exhibit a light transmittance of about 50% or more in a wavelength range of about 600 nm to about 800 nm.

In one or more embodiments, the base layer BS-F may have a maximum light transmittance in a wavelength range of about 500 nm to about 850 nm, and may exhibit a low light transmittance in a wavelength range of about 300 nm to about 500 nm. When the base layer BS-F of one or more embodiments is a polyimide film, the base layer BS-F may absorb light having a relatively shorter wavelength range of about 300 nm to about 500 nm, and may be configured to display a yellowish color.

In one or more embodiments, an absorbance of the base layer BS-F with respect to of first light may be about 80% or more. For example, the absorbance of the base layer BS-F with respect to the first light in a wavelength range of about 300 nm to about 500 nm may be about 80% or more.

The circuit layer D-CL may be on the base layer BS-F. The circuit layer D-CL may include a plurality of insulating layers, a plurality of transistors, a conductive pattern, a signal line, and/or the like. In one or more embodiments, a plurality of inorganic films, a plurality of organic films, a semiconductor layer, and a conductive layer may be formed through coating, deposition, and/or the like. Thereafter, the inorganic films, the organic films, the semiconductor layer, and the conductive layer may be patterned (e.g., selectively patterned) by performing a photolithography process. In this manner, the circuit layer D-CL including a plurality of insulating layers each formed from the inorganic films and the organic films, transistors including semiconductor patterns formed from the semiconductor layer, and a conductive pattern and a signal line formed from the conductive layer, and/or the like, may be formed. In FIG. 4, a configuration of the circuit layer D-CL is illustrated, and the transistors and signal lines, and/or the like, of the circuit layer D-CL may be electrically connected to light-emitting elements LD, and/or the like, of the display element layer D-EL.

Thereafter, the display element layer D-EL may be formed on the circuit layer D-CL, and the encapsulation layer TFE covering the display element layer D-EL may be formed.

The display element layer D-EL may include a pixel-defining layer PDL and the light-emitting element LD. The light-emitting element LD may include a first electrode AE, a light-emitting layer EL, and a second electrode CE.

The first electrode AE may be referred to as a pixel electrode. The first electrode AE may be formed of a metal material, metal alloy, and/or conductive compound. The first electrode AE may be an anode or a cathode. The first electrode AE may be a transmissive electrode, a transflective electrode, or a reflective electrode. When the first electrode AE is the transmissive electrode, the first electrode AE may include a transparent metal oxide, for example, indium tin oxide (ITO), indium zinc oxide (IZO), zinc oxide (ZnO), indium tin zinc oxide (ITZO), and/or the like. When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca, LiF/Al, Mo, Ti, W, or a compound or mixture thereof (for example, a mixture of Ag and Mg). In one or more embodiments, the first electrode AE may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), and the like. For example, the first electrode AE may have a three-layered structure of ITO/Ag/ITO, but is not limited thereto. The present disclosure is not limited thereto, and the first electrode AE may include the above-described metal materials, a combination of two or more metal materials selected from the above-described metal materials, oxides of the above-described metal materials, and/or the like.

The pixel-defining layer PDL may be on the circuit layer D-CL. In one or more embodiments, the pixel-defining layer PDL may be formed of a polymer resin. For example, the pixel-defining layer PDL may be formed of a polyacrylate-based resin and/or a polyimide-based resin. In one or more embodiments, the pixel-defining layer PDL may further include an inorganic material in addition to a polymer resin. In one or more embodiments, the pixel-defining layer PDL may be formed of a light absorbing material, and/or of a black pigment and/or a black dye. The pixel-defining layer PDL formed of a black pigment and/or a black dye may constitute a black pixel-defining layer. When forming the pixel-defining layer PDL, carbon black, and/or the like, may be used as a black pigment and/or a black dye, but one or more embodiments of the present disclosure is not limited thereto.

In one or more embodiments, the pixel-defining layer PDL may be formed of an inorganic material. For example, the pixel-defining layer PDL may be formed of silicon nitride, silicon oxide, silicon oxynitride, and/or the like.

A pixel opening for exposing a portion of the first electrode AE may be defined in the pixel-defining layer PDL. For example, a portion of the first electrode AE may be exposed by a pixel opening in the pixel-defining layer PDL. In the display module DM of one or more embodiments, light-emitting regions may be separated by the pixel-defining layer PDL. In the display module DM, the light-emitting region may be defined as a portion in which the first electrode AE does not overlap the pixel-defining layer PDL, is exposed, and overlaps the light-emitting layer EL. For example, a portion of the first electrode AE exposed by the opening in the pixel-defining layer PDL and overlapping the light emitting layer EL may define the light-emitting region.

In the light-emitting element LD, the light-emitting layer EL may be on the first electrode AE. In one or more embodiments, the light-emitting layer EL may be configured to emit light having at least one color of blue, red, or green. In one or more embodiments, the light-emitting layer EL may provide blue light in the entire active region AA (see FIG. 2). In one or more embodiments, the display module DM (see FIG. 2) may further include a light control part which converts a wavelength of light emitted from the light-emitting element LD.

The second electrode CE may be on the light-emitting layer EL. The second electrode CE may have an integral shape, and may be in common in a plurality of light-emitting elements in the active region AA (see FIG. 2). The second electrode CE may be referred to as a common electrode. The second electrode CE may be a cathode or an anode. For example, when the first electrode AE is an anode, the second electrode CE may be a cathode, and when the first electrode AE is a cathode, the second electrode CE may be an anode.

The second electrode CE may be a transmissive electrode, a transflective electrode, or a reflective electrode. When the second electrode CE is the transmissive electrode, the second electrode CE may include a transparent metal oxide, for example, indium tin oxide (ITO), indium zinc oxide (IZO), zinc oxide (ZnO), indium tin zinc oxide (ITZO), and/or the like. Additionally, the second electrode CE may be formed of Ag, Mg, Cu, Al, Pt, Pd, Au, Ni, Nd, Ir, Cr, Li, Ca, LiF/Ca, LiF/Al, Mo, Ti, W, or a compound or mixture thereof (for example, a mixture of Ag and Mg).

In one or more embodiments, a hole control layer may be between the first electrode AE and the light-emitting layer EL. The hole control layer may include a hole transport layer, and further include a hole injection layer. An electron control layer may be between the light-emitting layer EL and the second electrode CE. The electron control layer may include an electron transport layer and further include an electron injection layer. The hole control layer and the electron control layer may be formed, in common, in a plurality of light-emitting elements in the entire active region AA (see FIG. 2) by using an open mask.

The encapsulation layer TFE may be on the display element layer D-EL. The encapsulation layer TFE may include a first inorganic layer IL1, an organic layer OL, and a second inorganic layer IL2 which are sequentially stacked. However, layers constituting the encapsulation layer TFE are not limited thereto.

The inorganic layers IL1 and IL2 may protect the display element layer D-EL against moisture and oxygen, and the organic layer OL may protect the display element layer D-EL against foreign substances such as dust particles. The inorganic layers IL1 and IL2 may include at least one of silicon nitride, silicon oxynitride, silicon oxide, titanium oxide, or aluminum oxide. The organic layer OL may include an acylate-based organic material. However, the types (or kinds) of materials constituting the inorganic layers IL1 and IL2 and the organic layer OL are not limited thereto.

The input sensor ISP may be on the encapsulation layer TFE. In one or more embodiments, the input sensor ISP may include insulating layers and a sensor conductive layer. In one or more embodiments, the input sensor ISP may be directly on the encapsulation layer TFE.

The display module DM according to one or more embodiments may include the optical layer PL. In one or more embodiments, the optical layer PL may be directly on the input sensor ISP. However, one or more embodiments of the present disclosure is not limited thereto, and an adhesive layer, and/or the like, may also be further included between the optical layer PL and the input sensor ISP. The optical layer PL may be a reflection reduction layer which may be configured to reduce external light. In one or more embodiments, the optical layer PL may not be provided.

The light absorbing layer LAM of one or more embodiments may have a maximum light transmittance in a wavelength range of about 240 nm to about 550 nm. For example, the light absorbing layer LAM of one or more embodiments may have a maximum light transmittance in a wavelength range of about 300 nm to about 500 nm. In the display device ED of one or more embodiments, the light absorbing layer LAM may include at least one sub-light absorbing layer having a maximum light transmittance in a wavelength range of about 300 nm to about 500 nm. For example, the light absorbing layer LAM according to one or more embodiments may exhibit a light transmittance of about 20% or more in a wavelength range of about 300 nm to about 500 nm. For example, in one or more embodiments, the light absorbing layer LAM may exhibit a light transmittance of about 30% around a wavelength region of about 400 nm.

The light absorbing layer LAM and the base layer BS-F may respectively exhibit maximum light transmittances in different wavelength ranges. An absorbance of the base layer BS-F with respect to the first light may be about 80% or more, and an absorbance of the light absorbing layer LAM with respect to the second light may be about 80% or more. The second light may have a longer wavelength than the first light. For example, the first light has a wavelength of about 240 nm to about 550 nm, and the second light has a wavelength of about 500 nm to about 850 nm. For example, the first light has a wavelength in a wavelength range of about 300 nm to about 500 nm, and the second light has a wavelength in a wavelength range of about 500 nm to about 800 nm.

In one or more embodiments, the light absorbing layer LAM may have a maximum light transmittance in a wavelength range of about 300 nm to about 500 nm, and exhibit a low light transmittance in a relatively longer wavelength range of about 550 nm to about 800 nm. The light absorbing layer LAM may absorb light having a relatively longer wavelength range of about 550 nm to about 800 nm, and display a bluish color. In one or more embodiments, the light absorbing layer LAM may display a blue or green color.

The light absorbing layer LAM may include a base resin and a colorant. The light absorbing layer LAM may include a colorant to display a set or specific color. In one or more embodiments, a colorant included in the light absorbing layer LAM may include at least one of a blue colorant or a green colorant. A colorant may be a pigment and/or a dye. The light absorbing layer LAM may include both of a blue colorant and a green colorant in one layer, or may include colorants having colors different from each other in respective sub-light absorbing layers. In one or more embodiments, the light absorbing layer LAM may also include only a blue colorant. However, one or more embodiments of the present disclosure is not limited thereto, and the light absorbing layer LAM may include a colorant which has a color so as to be capable of absorbing light having a wavelength range not absorbed by the base layer BS-F among external light passing through the base layer BS-F and provided to a lower side of the display module DM.

In one or more embodiments, the light absorbing layer LAM may display a color complementary to a color which the base layer BS-F displays. Accordingly, the display device ED of one or more embodiments, which includes a stacked structure of the base layer BS-F and the light absorbing layer LAM displaying a complementary color thereto, may absorb most of light, in a visible light range, provided to a lower side of the display element layer D-EL.

The display device ED of one or more embodiments includes a stacked

structure of the base layer BS-F having a maximum light transmittance in a wavelength range of about 500 nm to about 850 nm, and the light absorbing layer LAM having a maximum light transmittance in a wavelength range of about 240 nm to about 550 nm, and may thus effectively or suitably absorb external light incident from the outside of the display device ED. For example, the display device ED of one or more embodiments includes a stacked structure of the base layer BS-F having a maximum light transmittance in a wavelength range of about 550 nm to about 800 nm, and the light absorbing layer LAM having a maximum light transmittance in a wavelength range of about 300 nm to about 500 nm, and may thus effectively or suitably absorb external light incident from the outside of the display device ED. For example, in the display device ED of one or more embodiments, when external light passes through the display element layer D-EL and is incident toward the base layer BS-F, the first light having a wavelength range of about 300 nm to about 500 nm is absorbed by the base layer BS-F, and the second light having a wavelength range of about 550 nm to about 800 nm, among light passing through the base layer BS-F and provided to the light absorbing layer LAM, is absorbed by the light absorbing layer LAM. Therefore, the display device ED may effectively or suitably absorb the external light incident from the outside.

In one or more embodiments, the light absorbing layer LAM may be directly below the base layer BS-F. The light absorbing layer LAM may be directly on the base layer BS-F without an additional adhesive member. The light absorbing layer LAM may be provided under the display module DM through coating to be formed. The light absorbing layer LAM may be provided under the display module DM in a state of an uncured light absorbing resin, and then may be formed by photocuring a coated light absorbing resin.

In one or more embodiments, the light absorbing layer LAM and the light absorbing resin from which the light absorbing layer LAM is formed may each have a maximum light transmittance in a wavelength range of about 240 nm to about 550 nm. In one or more embodiments, the light absorbing resin may have a maximum light transmittance in a wavelength range of about 300 nm to about 500 nm. For example, the light absorbing layer LAM and the light absorbing resin provided to form the light absorbing layer LAM may transmit ultraviolet light. Because the light absorbing resin is not configured to absorb and is not configured to transmit ultraviolet light, and/or the like, the light absorbing layer LAM having a high degree of cure may be formed without being uncured even when the light absorbing resin is provided to a suitable or sufficient thickness through coating. Therefore, the display device ED including the suitably or sufficiently cured light absorbing layer LAM may exhibit excellent or suitable reliability. For example, this is a more improved feature, compared to a case where a light absorbing layer including a black component is not cured because light for curing a light absorbing resin is also absorbed by the black component.

In one or more embodiments, in the display device ED, the light absorbing layer LAM may be configured to transmit light having a set or certain wavelength range, so that it is possible to determine, from a lower side of the light absorbing layer LAM, whether the display module DM is defective even after the light absorbing layer LAM is formed under the light absorbing layer LAM. In a display device including a light absorbing layer including a black component, the light absorbing layer has a low light transmittance in the entire visible light wavelength due to the black component, and thus there is a limitation of determining, from the lower side of the light absorbing layer, whether the display module is defective after the manufacturing of the display device. However, the light absorbing layer LAM included in the display device ED of one or more embodiments has a higher light transmittance in a set or specific wavelength range than a comparable light absorbing layer including a black component, and thus it is easier to visually recognize whether the display module DM is defective by providing light having a set or specific wavelength from the lower side of the light absorbing layer LAM. Accordingly, it is easier to visually recognize and determine whether the display module DM is defective during the manufacturing of the display device ED, and thus reworkability may be improved.

In one or more embodiments, the light absorbing layer LAM may be an optical member which is under the display module DM and may be configured to absorb light incident through the display module DM, and may also function as a support member for supporting the display module DM. The light absorbing layer LAM may have a thickness in a wavelength range of about 300 μm or more. The light absorbing layer LAM has a high light transmittance in a set or specific wavelength range, and may thus be provided to have a suitable or sufficient thickness without being uncured. Accordingly, the light absorbing layer LAM according to one or more embodiments may have a high light absorbance due to the suitable or sufficient thickness, support the display module DM from the lower side of the display module DM, and protect the display module DM, thereby exhibiting excellent or suitable display quality, improved reliability, and excellent or suitable durability.

For example, the display device ED of one or more embodiments includes a base layer BS-F and the light absorbing layer LAM under the base layer BS-F. Thus, external light is suitably or sufficiently absorbed by the stacked structure of the base layer BS-F and the light absorbing layer LAM, and the display device ED may exhibit good or suitable reflection reduction properties. Also, in the display device ED of one or more embodiments, the light absorbing layer LAM has a characteristic of transmitting light having a set or specific wavelength range, and may thus be formed to have a relatively high degree of cure. Accordingly, because outgassing caused by the non-curing of the light absorbing layer LAM and deterioration in durability of the light absorbing layer LAM are alleviated, the display device ED may exhibit excellent or suitable reliability.

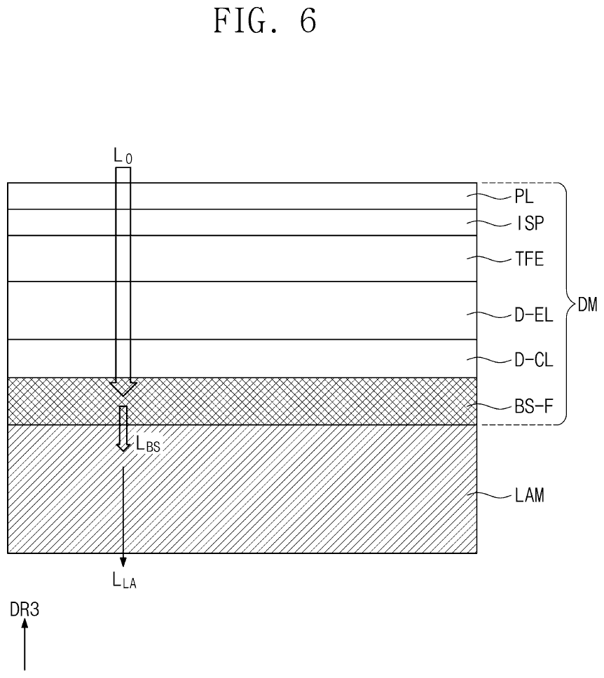

FIG. 6 illustrates steps of absorbing and transmitting external light in a display device ED of one or more embodiments. Referring to FIG. 6, in one or more embodiments, first external light Lo incident from the outside of the display device may pass through a display element layer D-EL to be provided to a base layer BS-F. Second external light LBs emitted through the base layer BS-F may be provided to the light absorbing layer LAM, transmit the light absorbing layer LAM, and finally, may be changed into third external light LLA.

Light having a set or certain wavelength range among the first external light L_{O} may be absorbed by the base layer BS-F. For example, in one or more embodiments, the base layer BS-F may absorb, among the first external light L_{O}, light having a short wavelength range of about 300 nm to about 500 nm, transmit light having a long wavelength range of about 550 nm to about 800 nm, and then provide the transmitted light to the light absorbing layer LAM as the second external light LBS. The light having a long wavelength range of about 550 nm to about 800 nm among the second external light LBs provided to the light absorbing layer LAM may be additionally absorbed by the light absorbing layer LAM. Light, among the first external light L_{O}, not absorbed by the base layer BS-F and the light absorbing layer LAM may pass through the light absorbing layer LAM as the third external light L_{LA}.

In one or more embodiments, the third external light L_{LA} corresponds to minimum external light not absorbed by the base layer BS-F and the light absorbing layer LAM, and the first external light L_{O} may be absorbed with a favorable absorbance in the entire visible light wavelength range while passing through the stacked structure of the base layer BS-F and the light absorbing layer LAM. Accordingly, the display device of one or more embodiments may favorably absorb external light to reduce reflection for external light, thereby exhibiting excellent or suitable display quality.

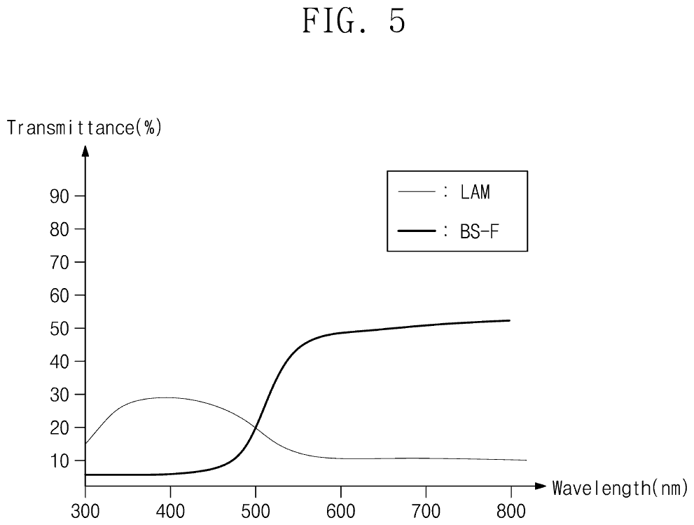

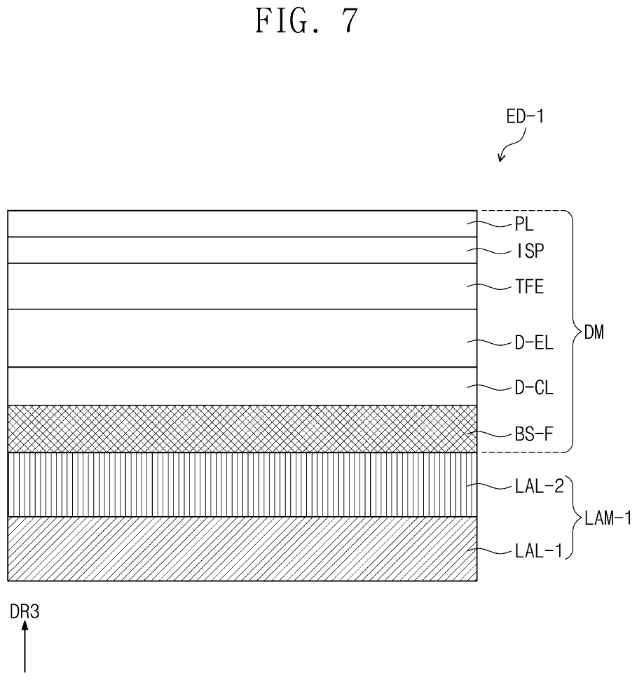

FIG. 7 is a cross-sectional view of a display device of one or more embodiments. A display device ED-1 of some aspects illustrated in FIG. 7 differs only in the configuration of a light absorbing layer LAM-1 from the display device ED of the one or more embodiments described with reference to FIGS. 1-5.

In the display device ED-1 of one or more embodiments, the light absorbing layer LAM-1 may include a plurality of sub-light absorbing layers. The light absorbing layer LAM-1 may include a first sub-light absorbing layer LAL-1 and a second sub-light absorbing layer LAL-2 between a base layer BS-F and the first sub-light absorbing layer LAL-1. In one or more embodiments, FIG. 7 illustrates only a case where the light absorbing layer LAM-1 includes two sub-light absorbing layers, but one or more embodiments of the present disclosure is not limited thereto. The light absorbing layer LAM-1 may have three or more sub-light absorbing layers. The plurality of sub-light absorbing layers may have respectively maximum light transmittances in wavelength ranges different from each other. In one or more embodiments, at least two layers among the plurality of sub-light absorbing layers may each have a maximum light transmittance in the same wavelength range.

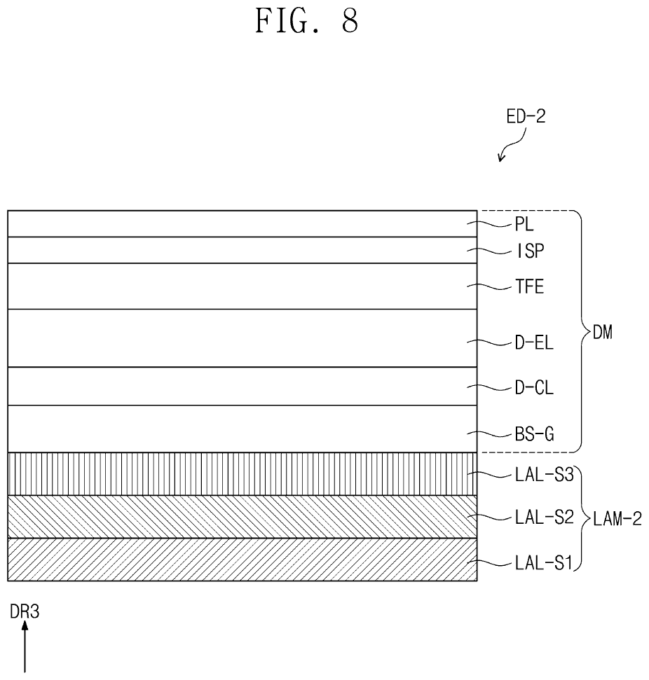

Hereinafter, the description of a display device of one or more embodiments will be made in more detail with reference to FIGS. 7-8, and/or the like. With regard to the descriptions of the display device of one or more embodiments described in more detail with reference to FIGS. 7-8, and/or the like, the contents duplicated with those described with the reference to FIGS. 1-6 will not be explained again and the following description will be mainly focused on the differences.

In one or more embodiments illustrated in FIG. 7, the first sub-light absorbing layer LAL-1 and the second sub-light absorbing layer LAL-2 may exhibit maximum light transmittances in wavelength ranges different from each other. In one or more embodiments, the second sub-light absorbing layer LAL-2 may have a maximum light transmittance in a relatively longer wavelength range than the first sub-light absorbing layer LAL-1. In one or more embodiments, for example, the first sub-light absorbing layer LAL-1 may have a maximum light transmittance in a wavelength range of about 300 nm to about 500 nm, and the second sub-light absorbing layer LAL-2 may have a maximum light transmittance in a wavelength range of about 500 nm to about 600 nm.

In one or more embodiments, the first sub-light absorbing layer LAL-1 and the second sub-light absorbing layer LAL-2 may be recognized as colors different from each other. For example, the first sub-light absorbing layer LAL-1 and the second sub-light absorbing layer LAL-2 may have colors different from each other. For example, the first sub-light absorbing layer LAL-1 may be recognized as blue, and the second sub-light absorbing layer LAL-2 may be recognized as green. For example, the first sub-light absorbing layer LAL-1 may have a blue color and the second sub-light absorbing layer LAL-2 may have a green color. In one or more embodiments, the first sub-light absorbing layer LAL-1 may include a blue colorant, and the second sub-light absorbing layer LAL-2 may include a green colorant. However, one or more embodiments of the present disclosure is not limited thereto. In one or more embodiments, if a wavelength range, in which light is maximally absorbed by the light absorbing layer LAM including the first sub-light absorbing layer LAL-1 and the second sub-light absorbing layer LAL-2, and a wavelength range, in which light is maximally absorbed by the base layer BS-F, do not overlap and are complementary to each other, a configuration of each layer of the first sub-light absorbing layer LAL-1 and the second sub-light absorbing layer LAL-2 may be different from what is illustrated above.

In one or more embodiments, the first sub-light absorbing layer LAL-1 and the second sub-light absorbing layer LAL-2 may exhibit light absorbances in wavelength ranges different from each other. For example, the first sub-light absorbing layer LAL-1 may have a maximum light absorbance in a wavelength range of about 600 nm or more, and the second sub-light absorbing layer LAL-2 may have a maximum light absorbance in about 300 nm to about 400 nm. In one or more embodiments, the base layer BS-F may have a maximum light absorbance in about 300 nm to about 600 nm.

The display device ED-1 of one or more embodiments includes the base

layer BS-F, and the light absorbing layer LAM-1 including the second sub-light absorbing layer LAL-2 and the first sub-light absorbing layer LAL-1 which have maximum light transmittances in wavelength ranges different from each other and are sequentially arranged below the base layer BS-F. Thus, external light provided from outside of the display device ED-1 is effectively or suitably absorbed, and the display device ED-1 may exhibit a characteristic of preventing or reducing reflected light from being viewed. For example, the display device ED-1 of one or more embodiments may have a stacked structure of the base layer BS-F and the light absorbing layer LAM-1 which is configured to absorb light having a wavelength range different from that of the base layer BS-F. Thus, external light is effectively or suitably absorbed, and the display device ED-1 may exhibit excellent or suitable display quality. In one or more embodiments, because the sub-light absorbing layers LAL-1 and LAL-2 of the light absorbing layer LAM-1 each have a light transmittance of about 20% or more in a set or specific wavelength range, the sub-light absorbing layers LAL-1 and LAL-2 may be formed by using light having a wavelength range of which the light transmittance is about 20% or more. Accordingly, the sub-light absorbing layers LAL-1 and LAL-2 have a relatively high degree of cure, and thus the display device ED-1 may exhibit the excellent or suitable reliability.

FIG. 8 is a cross-sectional view of a display device of one or more embodiments. In a display device ED-2 of one or more embodiments, a base layer BS-G may include a glass substrate. In one or more embodiments, the base layer BS-G may include a transparent glass substrate. For example, the base layer BS-G may include a transparent glass substrate having a light transmittance of about 80% or more in a wavelength range of about 300 nm to about 800 nm.

Referring to FIG. 8, a light absorbing layer LAM-2 may be directly below the base layer BS-G. In one or more embodiments, the light absorbing layer LAM-2 may include a first sub-light absorbing layer LAL-S1 having a maximum light transmittance in a wavelength range of about 300 nm to about 450 nm, a second sub-light absorbing layer LAL-S2 between the first sub-light absorbing layer LAL-S1 and the base layer BS-G and having a maximum light transmittance in a wavelength range of about 500 nm to about 600 nm, and a third sub-light absorbing layer LAL-S3 between the second sub-light absorbing layer LAL-S2 and the base layer BS-G and having a maximum light transmittance in a wavelength range of about 650 nm to about 800 nm.

In one or more embodiments, the third sub-light absorbing layer LAL-S3 may be directly below the base layer BS-G. Also, in one or more embodiments, the second sub-light absorbing layer LAL-S2 may be directly below the third sub-light absorbing layer LAL-S3, and the first sub-light absorbing layer LAL-S1 may be directly below the second sub-light absorbing layer LAL-S2. The third sub-light absorbing layer LAL-S3, the second sub-light absorbing layer LAL-S2, and the first sub-light absorbing layer LAL-S1 may be formed to be sequentially below the base layer BS-G of a display module DM. For example, the first sub-light absorbing layer LAL-S1, the second sub-light absorbing layer LAL-S2, and the third sub-light absorbing layer LAL-S3 may be sequentially stacked in a third direction DR3.

In the display device ED-2 of one or more embodiments, external light provided through the display module DM may be effectively or suitably absorbed by the light absorbing layer LAM-2 including the plurality of sub-light absorbing layers LAL-S1, LAL-S2, and LAL-S3. For example, the third sub-light absorbing layer LAL-S3 may be configured to absorb light in a wavelength range of about 300 nm to about 600 nm with a light absorbance of about 80% or more, the second sub-light absorbing layer LAL-S2 may be configured to absorb light in a wavelength range of about 300 nm to about 450 nm, and about 650 nm to about 800 nm with a light absorbance of about 80% or more, and the first sub-light absorbing layer LAL-S1 may be configured to absorb light in a wavelength range of about 500 nm to about 800 nm with a light absorbance of about 80% or more. Accordingly, even if the base layer BS-G has a high transmittance, external light provided to the display device ED-2 may be effectively or suitably absorbed by the light absorbing layer LAM. Therefore, the display device ED-2 of one or more embodiments may reduce external light reflection, thereby exhibiting excellent or suitable display quality.

FIG. 9 shows transmittance properties versus the wavelengths of the sub-light absorbing layers included in the light absorbing layer LAM-2, according to some aspects illustrated in FIG. 8. First to third sub-light absorbing layers LAL-S1, LAL-S2, and LAL-S3 exhibit maximum light transmittances in wavelength ranges different from each other. For example, in one or more embodiments, the first sub-light absorbing layer LAL-S1 may exhibit a maximum light transmittance in a shorter wavelength range than the second sub-light absorbing layer LAL-S2, and the third sub-light absorbing layer LAL-S3 may exhibit a maximum light transmittance in a longer wavelength range than the second sub-light absorbing layer LAL-S2. The first to third sub-light absorbing layers LAL-S1, LAL-S2, and LAL-S3 have a difference in maximum light transmittance-wavelength characteristic so as to complement each other. Accordingly, the first to third sub-light absorbing layers LAL-S1, LAL-S2, and LAL-S3 may be complementary to each other to absorb light in different wavelength ranges and thus effectively or suitably absorb the light. Therefore, the display device including the first to third sub-light absorbing layers LAL-S1, LAL-S2, and LAL-S3 may exhibit excellent or suitable external light absorption properties.

In one or more embodiments, FIGS. 8-9 illustrate that the light absorbing layer LAM-2 includes three sub-light absorbing layers, but one or more embodiments of the present disclosure is not limited thereto. In one or more embodiments, in the case of the display device ED-2 including a glass substrate in which the base layer BS-G has a high transmittance in the entire visible light range, the light absorbing layer LAM-2 may have a stacked structure of two sub-light absorbing layers, or a stacked structure of four or more sub-light absorbing layers, as long as the structure is capable of effectively or suitably absorbing light in a visible light range.

In the display device ED-2 of one or more embodiments, the first to third sub-light absorbing layers LAL-S1, LAL-S2, and LAL-S3 have properties of a light transmittance being higher than a set or predetermined transmittance at a set or specific wavelength, compared to a comparable light absorbing layer including a black component, and may thus be effectively or suitably cured using ultraviolet light, infrared light, and/or the like such that non-curing is minimized or reduced. Accordingly, the display device ED-2 of one or more embodiments may exhibit excellent or suitable reliability.

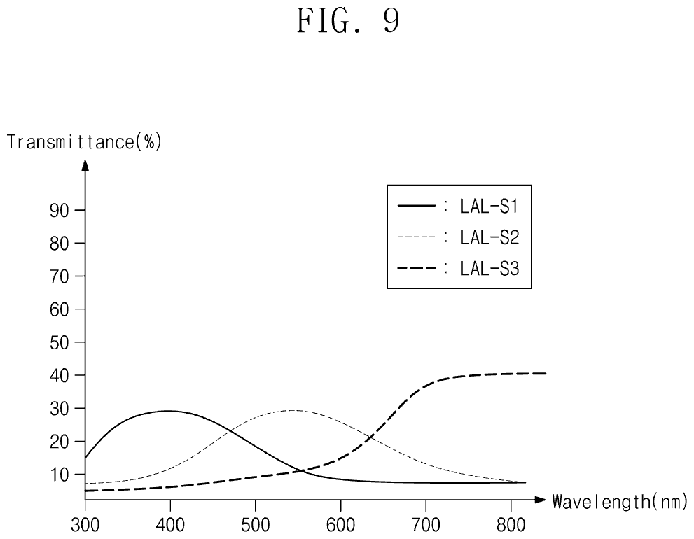

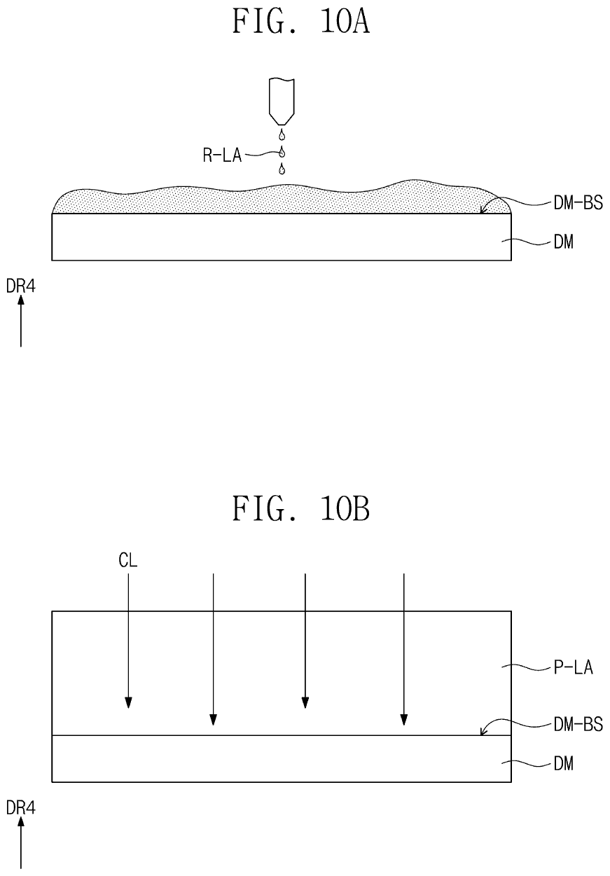

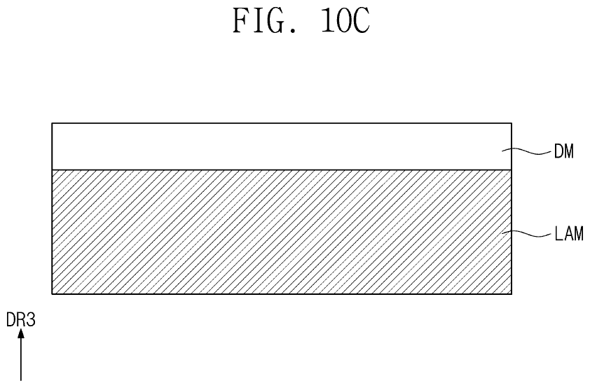

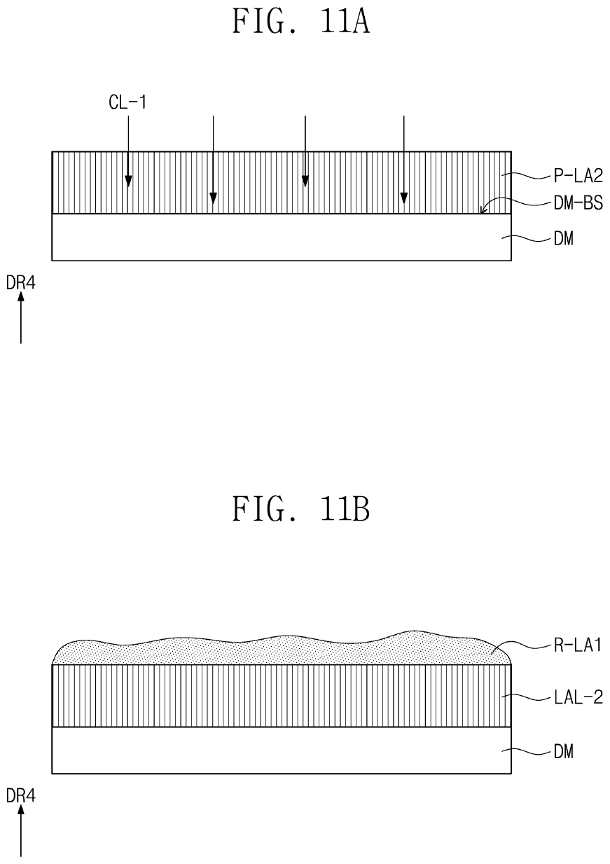

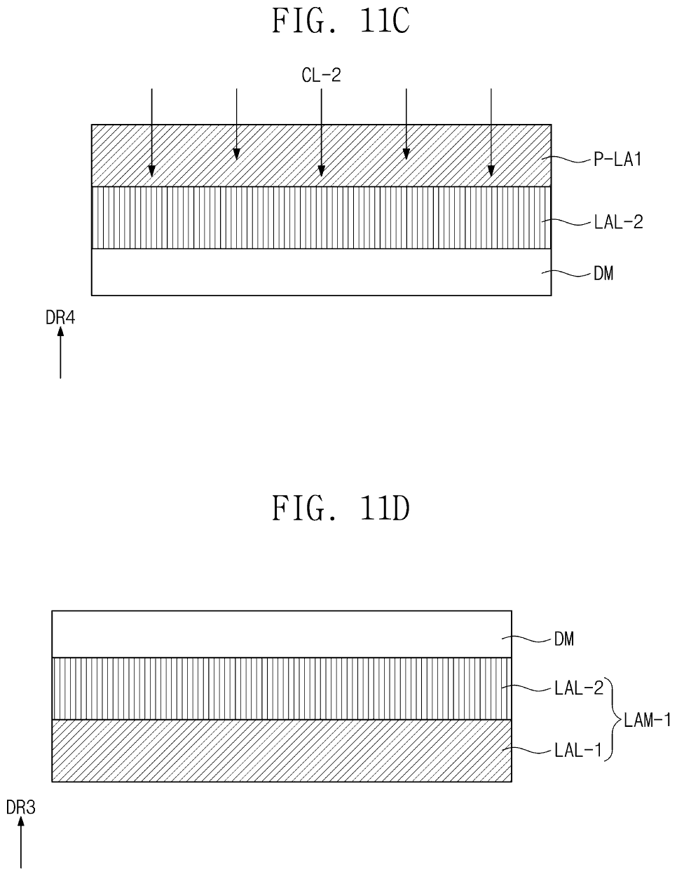

Hereinafter, FIGS. 10A-11D are views illustrating some steps of a method for manufacturing a display device of one or more embodiments. In the description of the method for manufacturing the display device, of one or more embodiments, described in more detail with the references to FIGS. 10A-11D, the contents duplicated with those of the display device, of one or more embodiments, described in more detail with reference to FIGS. 1-9 will not be explained again, and the following description will be mainly focused on the differences.

FIGS. 10A-10C illustrate some steps of the method for manufacturing the display device according to one or more embodiments. FIGS. 10A-10C may illustrate steps of manufacturing the display device ED, of some aspects illustrated in FIG. 4.

FIG. 10A illustrates a step of providing a light absorbing resin for manufacturing a light absorbing layer. FIG. 10B illustrates a curing step of manufacturing the light absorbing layer, and FIG. 10C illustrates a stacked structure of a part of the display device manufactured after the curing step.

Referring to FIG. 10A, a light absorbing resin R-LA may be provided to a lower surface DM-BS of a display module DM. The light absorbing resin R-LA may include an uncured base resin, a colorant, and a photocuring agent. The light absorbing resin R-LA may be coated onto the lower surface DM-BS of the display module DM. In one or more embodiments, the light absorbing resin R-LA may be directly provided below the base layer BS-F (see FIG. 4).

FIG. 10B illustrates a curing step of manufacturing the light absorbing layer, and FIG. 10C illustrates a stacked structure of a part of the display device manufactured after the curing step. A light source LC for curing may be provided to a preliminary light absorbing layer P-LA which is provided to a set or predetermined thickness by coating the light absorbing resin R-LA. For example, the light source LC may be ultraviolet light. However, one or more embodiments of the present disclosure is not limited thereto. The light absorbing resin R-LA may have a maximum light transmittance in a wavelength range of about 240 nm to about 550 nm. Accordingly, the ultraviolet light may be provided in the entire region of the light absorbing resin R-LA and the preliminary light absorbing layer P-LA which is provided by coating the light absorbing resin R-LA. For example, in one or more embodiments, the light source LC is provided up to a region of the preliminary light absorbing layer P-LA adjacent to the lower surface DM-BS of the display module DM, and thus the preliminary light absorbing layer P-LA may be sufficiently or suitably cured. Therefore, the light absorbing layer may be provided without being uncured, and thus the display device of one or more embodiments may exhibit improved reliability.

The preliminary light absorbing layer P-LA is cured and finally, the light

absorbing layer LAM may be formed. The light absorbing layer LAM may have a maximum light transmittance in a wavelength range of about 300 nm to about 500 nm, and have a maximum light absorbance in a wavelength range of about 550 nm to about 800 nm.

FIGS. 11A-11D illustrate some steps of a method for manufacturing a

display device according to one or more embodiments. In the display device of one or more embodiments manufactured through some steps of the method for manufacturing the display device illustrated in FIGS. 11A-11D, the light absorbing layer may include a plurality of sub-light absorbing layers. For example, FIGS. 11A-11D may illustrate methods for manufacturing the display device of one or more embodiments described in more detail with reference to FIG. 7.

The display device including the plurality of sub-light absorbing layers may be manufactured through the steps of FIGS. 11A-11D. A light absorbing layer LAM-1 including a plurality of sub-light absorbing layers LAL-1 and LAL-2 may be manufactured by repeatedly performing a process of sequentially coating and curing a light absorbing resin on a lower surface DM-BS of a display module DM.

FIG. 11A illustrates a step of providing light of a first light source CL-1 to a second preliminary sub-layer P-LA2 provided for manufacturing the second sub-light absorbing layer LAL-2 to the lower surface DM-BS of the display module DM. FIG. 11B illustrates a step of providing a first light absorbing resin R-LA1 to manufacture the first sub-light absorbing layer LAL-1 after the forming of the second sub-light absorbing layer LAL-2. FIG. 11C illustrates a step of providing light of a second light source CL-2 to the first preliminary sub-layer P-LA1. FIG. 11D illustrates a stacked structure of the display device including the light absorbing layer LAM-1 manufactured through the steps of FIGS. 11A-11C.

The second preliminary sub-layer P-LA2 may have a maximum light transmittance in a wavelength range of about 500 nm to about 600 nm, and the first preliminary sub-layer P-LA1 may have a maximum light transmittance in a wavelength range of about 300 nm to about 500 nm. However, one or more embodiments of the present disclosure is not limited thereto. The first preliminary sub-layer P-LA1 and the second preliminary sub-layer P-LA2 may have a maximum light transmittance in the same wavelength range, or may exhibit light transmittance properties of being capable of absorbing light in a wavelength range different from the above-described wavelength range but in a manner of being complementary to each other.

The first light source CL-1 and the second light source CL-2, which are used to cure the second preliminary sub-layer P-LA2 and the first preliminary sub-layer P-LA1, may be light sources for curing with light in different wavelength ranges. For example, light of the first light source CL-1 may be infrared light, and light of the second light source CL-2 may be ultraviolet light. However, one or more embodiments of the present disclosure is not limited thereto. For example, in one or more embodiments, light of each of the first light source CL-1 and the second light source CL-2 may be ultraviolet light.

As described in more detail with reference to FIGS. 11A-11C, to manufacture the light absorbing layer including a plurality of sub-light absorbing layers, coating and curing of a light absorbing resin may be performed repeatedly in order of being adjacent to the lower surface of the display module. In one or more embodiments, the light absorbing resin from which the sub-light absorbing layers are formed has a light transmittance of about 20% or more in a set or specific wavelength range, compared to a comparable light absorbing resin including a black component, and thus may be sufficiently or suitably cured using light having a set or specific wavelength range. Therefore, the plurality of sub-light absorbing layers may also be provided without being uncured, and thus the display device of one or more embodiments may exhibit the improved reliability.

In one or more embodiments, the light absorbing layer LAM-1 formed by stacking the plurality of sub-light absorbing layers may have a maximum light transmittance in a wavelength range of about 300 nm to about 600 nm, and may have a maximum light absorbance in a wavelength range of about 600 nm to about 800 nm. Accordingly, a display device including the light absorbing layer LAM-1 of one or more embodiments may effectively or suitably absorb external light, thereby exhibiting excellent or suitable display quality.

A display device of one or more embodiments includes a light absorbing

layer which is under a display module, has a maximum light transmittance in a set or specific wavelength range, and is configured to absorb light having a set or certain wavelength range, and may thus exhibit excellent or suitable display quality by effectively or suitably absorbing portion of external light provided to the display device and preventing or reducing reflected light from being viewed from the outside. A display device of one or more embodiments may include a light absorbing layer having a maximum light transmittance in a set or specific wavelength range. Thus, the excellent or suitable reliability may be exhibited because the light absorbing layer is sufficiently or suitably cured by light having the set or specific wavelength range.

Further, a display device of one or more embodiments includes a base layer, which is included in a display module and is configured to absorb first light, and a light absorbing layer which is configured to absorb second light different from the first light in a manner of being complementary to the base layer, and thus external light may be effectively or suitably absorbed by a stacked structure of the base layer and the light absorbing layer. Accordingly, the external light provided from the outside of the display device is complementarily absorbed while being passed through the stacked structure of the base layer and the light absorbing layer. Thus, reflection for external light is reduced, and the display device of one or more embodiments may exhibit excellent or suitable display quality.

A display device according to one or more embodiments may include a light absorbing layer which is under a base layer and has a maximum light transmittance in a wavelength range of about 550 nm or less, and thus may exhibit excellent or suitable reliability because the light absorbing layer is cured so as to have a relatively high degree of cure through a photocuring method.

The display device according to one or more embodiments may reduce reflection for external light because the light absorbing layer which is configured to absorb light having a set or certain wavelength range is under the base layer.

An electronic device according to one or more embodiments of the present disclosure includes the preceding display device as described herein. In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

Although embodiments of the present disclosure have been described, it is understood that the present disclosure should not be limited to these embodiments but one or more suitable changes and modifications can be made by one of ordinary skilled in the art within the spirit and scope of the present disclosure as hereinafter claimed.

Therefore, the technical scope of the present disclosure is not limited to the contents described in the detailed description of the specification, but should be determined by the appended claims, and equivalents thereof.

What is claimed is:

1. A display device comprising:
a base layer;
a display element layer on the base layer; and
a light absorbing layer under the base layer and having a maximum light transmittance in a wavelength range of about 240 nm to about 550 nm.

2. The display device of claim 1, wherein the base layer comprises a polyimide film having flexibility.

3. The display device of claim 2, wherein the base layer has a maximum light transmittance in a wavelength range of about 500 nm to about 850 nm.

4. The display device of claim 3, wherein the light absorbing layer comprises:
a first sub-light absorbing layer having a maximum light transmittance in a first wavelength range; and
a second sub-light absorbing layer between the first sub-light absorbing layer and the base layer and having a maximum light transmittance in a second wavelength range having a wavelength longer than the first wavelength range.

5. The display device of claim 1, wherein the base layer comprises a transparent glass substrate having a light transmittance of about 80% or more in a wavelength range of about 300 nm to about 800 nm.

6. The display device of claim 5, wherein the light absorbing layer comprises:
a first sub-light absorbing layer having a maximum light transmittance in a wavelength range of about 300 nm to about 450 nm;
a second sub-light absorbing layer between the first sub-light absorbing layer and the base layer and having a maximum light transmittance in a wavelength range of about 500 nm to about 600 nm; and
a third sub-light absorbing layer between the second sub-light absorbing layer and the base layer and having a maximum light transmittance in a wavelength range of about 650 nm to about 800 nm.

7. The display device of claim 1, wherein the light absorbing layer comprises a base resin, and at least one colorant of a blue colorant or a green colorant.

8. The display device of claim 1, wherein the light absorbing layer is directly below the base layer.

9. A display device comprising:
a base layer having a maximum light transmittance in a first wavelength range;
a display element layer on the base layer and comprising a light-emitting element; and
a light absorbing layer under the base layer and having a maximum light transmittance in a second wavelength range having a shorter wavelength than the first wavelength range.

10. The display device of claim 9, wherein the base layer is a polyimide film having a maximum light transmittance in a wavelength range of about 500 nm to about 850 nm.

11. The display device of claim 10, wherein the light absorbing layer comprises a first sub-light absorbing layer having a maximum light transmittance in a wavelength range of about 300 nm to about 450 nm.

12. The display device of claim 11, wherein the light absorbing layer further comprises a second sub-light absorbing layer between the first sub-light absorbing layer and the base layer and having a maximum light transmittance in a wavelength range of about 500 nm to about 600 nm.

13. The display device of claim 12, wherein the second sub-light absorbing layer is directly below the base layer, and
the first sub-light absorbing layer is directly below the second sub-light absorbing layer.

14. The display device of claim 9, wherein the light absorbing layer is directly below the base layer.

15. The display device of claim 9, further comprising an optical layer on the display element layer and comprising a polarization layer.

16. A display device comprising:
a display element layer comprising a light-emitting element;
a base layer below the display element layer and having an absorbance of first light of about 80% or more; and
1 a light absorbing layer directly below the base layer and having an absorbance of second light of about 80% or more, the second light having a longer wavelength than the first light.

17. The display device of claim 16, wherein the first light has a wavelength in a range of about 240 nm to about 550 nm, and the second light has a wavelength in a range of about 500 nm to about 850 nm.

18. The display device of claim 16, wherein the light absorbing layer is configured to transmit ultraviolet light.

19. The display device of claim 16, wherein the light absorbing layer comprises a plurality of sub-light absorbing layers, and
the sub-light absorbing layers comprise
a first sub-light absorbing layer below the base layer and configured to transmit ultraviolet light, and
a second sub-light absorbing layer between the first sub-light absorbing layer and the base layer, and configured to absorb the ultraviolet light and configured to transmit infrared light.

20. The display device of claim 16, wherein the base layer is a polyimide film, and
the light absorbing layer comprises at least one of a blue colorant or a green colorant.

21. An electronic device comprising:
a display device comprising:
a base layer;
a display element layer on the base layer; and
a light absorbing layer under the base layer and having a maximum light transmittance in a wavelength range of about 240 nm to about 550 nm.

22. The electronic device of claim 21, wherein the electronic device is a smartphone, a high-resolution smartphone, a mobile phone, a smart pad, a smart watch, a tablet PC, an electric vehicle, a vehicle navigation system, a television, a computer monitor, a laptop computer, a mobile communication terminal, an electronic notebook, a portable multimedia player (PMP), an ultra-mobile PC (UMPC), a computer, a billboard, an Internet of Things (IoT) device, a watch phone, a head-mounted displays (HMD), and a combination thereof.
